(19) United States
(12) Patent Application Publication
(10) Pub. No.: US 2010/0294352 A1
(43) Pub. Date: Nov. 25, 2010

(54) METAL PATTERNING FOR ELECTRICALLY CONDUCTIVE STRUCTURES BASED ON ALLOY FORMATION

(76) Inventors: Uma Srinivasan, Mountain View, CA (US); Neeraj Pakala, Cupertino, CA (US); William A. Sanders, Palo Alto, CA (US); Henry Hieslmair, San Francisco, CA (US)

Correspondence Address: DARDI & HERBERT, PLLC, Moore Lake Plaza, Suite 205, 1250 East Moore Lake Drive, Fridley, MN, 55432, US

(21) Appl. No.: 12/469,101

(22) Filed: May 20, 2009

(51) Int. Cl. H01L 31/00; C22F 1/00; C21D 1/34; B32B 3/00; H01L 21/306

(52) U.S. Cl. 136/256; 148/527; 148/525; 428/601; 438/745; 257/E21.219

(57) ABSTRACT

Layered metal structures are patterned to form a surface with some locations having an alloy along the top surface at some locations and the original top metal layer at other locations along the surface. The alloy and original top metal layer can be selected to have differential etching properties such that the pattern of the alloy or original metal can be selectively etched to form a patterned metal interconnect. In general, the patterning is performed by localized heating that drives formation of the alloy at the heated locations. The metal patterning can be useful for solar cell applications as well as for electronics applications, such as display applications.

### FIELD OF THE INVENTION

The invention relates to structures of patterned metal, electrically conductive contacts especially for circuit formation, which can be formed on semiconductor based structures. The invention further relates to light driven alloying methods for the formation of metal contacts and related processing methodologies. The metal contacts can be used, for example, for solar cell current collectors or for large area electrical circuits.

### BACKGROUND OF THE INVENTION

Electrical interconnects within electronic devices and the like can provide desired electrical connectivity. Metal is often used for providing electrical transmission due to the low electrical resistance generally exhibited by metal. Semiconductor materials are broadly used in commercial electronic devices for the formation of functional elements. In many components, semiconductor based elements can be patterned on a larger substrate. Layers can be correspondingly patterned to provide appropriate relationships between the elements. Generally, electrical conductors can be deposited to form appropriate electrical connections between the elements. While conventional photolithographic techniques can be used to pattern semiconductor-based components and related structures, the cost and complexity of photolithographic approaches can be undesirable for very large area substrates and/or for less expensive applications. Semiconductor-based structures can be, for example, components of electrical devices, display devices or photovoltaic devices.

Various technologies are available for the formation of photovoltaic cells, e.g., solar cells, in which a semiconducting material functions as a photoconductor. A majority of commercial photovoltaic cells are based on silicon. With non-renewable energy sources continuing to be less desirable due to environmental and cost concerns, there is continuing interest in alternative energy sources, especially renewable energy sources. Increased commercialization of renewable energy sources relies on increasing cost effectiveness through lower costs per energy unit, which can be achieved through improved efficiency of the energy source and/or through cost reduction for materials and processing. Thus, for a photovoltaic cell, commercial advantages can result from increased energy conversion efficiency for a given light fluence and/or from lower cost of producing a cell.

### SUMMARY OF THE INVENTION

In a first aspect, the invention pertains to a structure comprising a substrate and an electrically conductive material forming a pattern on the surface of the substrate. The electrically conductive material has a first layer adjacent to the substrate comprising a first elemental metal and a second layer on the first layer comprising a second elemental metal different from the first elemental metal. In general, a spacing between at least some adjacent segments of the pattern is at least about 5 microns. Furthermore, the first elemental metal and the second elemental metal can form an alloy with each other, and the relative amounts of the first metal and the second metal can provide for the incorporation of the second metal into the alloy with at least a portion of the first metal.

In a further aspect, the invention pertains to a structure comprising an inorganic substrate and an electrically conductive layer on the substrate. In some embodiments, the electrically conductive layer comprises first sections with a first layer adjacent the substrate comprising a first elemental metal and a second layer over the first layer comprising a second elemental metal, and second sections having a composition comprising an alloy of the first metal and the second metal.

In another aspect, the invention pertains to a method for patterning an electrically conductive layer on a substrate. The method comprises applying localized heating along the surface of the electrically conductive layer. In general, the electrically conductive layer comprises a first layer adjacent the substrate comprising a first elemental metal and a second layer on the first layer comprising a second elemental metal. The localized heating forms an alloy of the first metal and the second metal in a pattern according to the locations at which the heat is applied.

### BRIEF DESCRIPTION OF THE DRAWINGS

FIG. 1 is a schematic perspective view of a structure with patterned metal forming electrical interconnects.

FIG. 2 is a sectional view of the structure of FIG. 1 taken along lines 2-2 of FIG. 1.

FIG. 3 is top plan view of interdigitated patterned metal current collectors for a rear contact solar cell.

FIG. 4 is a photomicrograph of a lattice pattern of a trench through nickel coated aluminum that exposes silicon oxide below the aluminum.

FIG. 5 is a photomicrograph of a pattern of a trench through nickel coated aluminum that exposes silicon oxide below the aluminum.

FIG. 6 is an enlarged view of a section of the photomicrograph of FIG. 5 showing a straight line section of the trench pattern.

FIG. 7 is an enlarged view of a section of the photomicrograph of FIG. 5 showing a u-turn section of the trench pattern.

FIG. 8 is a photomicrograph of another trench pattern through nickel coated aluminum that exposes silicon oxide below the aluminum.

FIG. 9 is a photomicrograph of an additional trench pattern formed using an etch after an alloy is formed through multiple passes of a laser beam in which the trench is cut through nickel coated aluminum to expose silicon nitride below the aluminum.

### DETAILED DESCRIPTION OF THE INVENTION

Light driven alloy formation has been discovered to be a relatively low thermal budget process that provides for the selective removal of the alloy and an underlying metal while an adjacent metal stack remains substantially intact to form an electrical interconnect. The resulting electrical interconnect structure can have a desired metal pattern that can provide appropriate electrical conduction pathways for the operation of the particular device. The alloying step can be performed as a simpler alternative to the use of patterning with a mask or with respect to ablating metal from the structure with the laser, which requires significantly higher amounts of energy and has additional drawbacks relating to potential damage to the underlying structure. The selection of an appropriate metal stack provides for an alloy formation while leaving an original top metal layer at locations where the alloy is not formed. In some embodiments, the original top metal layer provides an etch resistant material for selective etching, although in some embodiments the alloy can be the etch resistant material. In some embodiments, the alloy can be selected to be preferentially removed in an etching step relative to the etch resistant top metal layer at locations where the alloy is not formed. High quality electrical contacts can be formed using this approach in a convenient and efficient approach.

In general, electronic devices, such as semiconductor-based devices, have metal interconnects to provide desired electrical connectivity between elements of the device. To provide the desired electrical connections without significant electrical short-circuits along undesired conduction pathways, the metal interconnects are patterned along a selected design to provide desired connectivity. Specifically, intact metal networks form desired electrical conduction pathways, and gaps between the metal formations provide electrically insulating domains to isolate adjacent electrical conduction pathways. During processing, it is desired that the metal formations that remain following patterning are sufficiently intact that they provide low electrical resistance pathways, and at the locations where metal is removed to form the electrically insulating gaps, the metal should be sufficiently removed such that there is little short circuiting between the adjacent isolated sections of conduction pathway. As described herein, the electrical connectivity can be selected along a desired path through a guided light beam, e.g., a laser beam, that scans the portion of the surface along the selected portion for the formation of a metal alloy from metals of a top layer and a lower layer. Thus, relative complex patterns can be formed with relatively small spacing between the conductive structures.

The metal interconnects are generally formed over a substrate that has an underlying pattern related to the function of the particular device. The metal interconnects are then patterned to correspond with the pattern of the functional components of the device to support the device function. In some embodiments, the electrical interconnects can be patterned to form counter electrodes or more complex patterns to provide access to more complex interconnected elements, such as within an electrical circuit.

As used herein including the claims, when the term metal is used without qualification, the term refer to a metal element in an elemental state, a doped version of a metal element in an elemental state or an alloy thereof. Reference to elemental metal refers to the elemental form of the material, i.e., the unoxidized, M⁰, where M represents the metal element. Metal elements generally can be oxidized to form other oxidation states which then are generally associated with a metal composition, such as a metal oxide, etc. Alloys are solid solutions, and metal alloys involve either mixtures of elemental metals or metals with low amounts of other elements dissolved into the metal. For example, iron can dissolve up to about 2.14 weight percent carbon to form the alloy steel without any phase separation into iron carbide, a metal compound. Metal alloys generally maintain their high electrical conductivity similar to a pure metal.

In general, the processes described herein involve the formation of a metal alloy involving two or more metals in a solid metal solution. Generally there are significant amounts of each metal in the alloy. To form the alloy, a layered structure is formed, and the top layer is heated with light. The heating along the top metal layer drives the alloy formation in which the top layer is then dissolved into at least a portion of the bottom layer. In some embodiments, a surface alloy is formed with a portion of the lower metal layer remaining intact. For some proportion of metals in the alloy, a eutectic mixture can be formed which has a single melting point. The eutectic alloy can have a low melting point.

In preparation for performing the metal patterning, a plurality of metal layers is formed. Ultimately, metal is removed from selected locations to leave a pattern for electrically conductive interconnects. In some embodiments, at least the lower electrically conductive layer can be maintained in the ultimate structure following patterning to provide electrical connectivity. If a layered metal structure remains after etching, an upper metal layer may or may not be removed after patterning for the formation of the ultimate structure. Generally, simpler overall processing can involve maintaining a top metal layer in the electrical interconnects, and some upper layer metals can be convenient with respect to providing external electrical connections to the device.

Within the overall structure, the layers of metal can be placed onto a dielectric layer such that the dielectric layer does not provide any electrical connectivity along the surface. However, the dielectric layer generally can be patterned prior to depositing the metal layers to provide desired access of the metal interconnects with respect to underlying semiconductor and/or electrically conductive material that provide functionality that is accessed through the metal interconnects. In other words, a dielectric layer generally has windows or the like to provide for connections of a metal in interconnect with underlying functional components. The patterning of the metal interconnects generally can be based on appropriate conductivity with respect to the functional material accessed through windows in the dielectric. Furthermore, external electrical connections can be made to the patterned electrical interconnects to connect the structure with external circuits.

Many electronic devices are formed from semiconductor materials which can be patterned into functional devices, such as through the patterning of dopants within the semiconductor. Complex electronic structures can be patterned on the semiconductor material. In some embodiments, these structures form integrated electrical circuits. The electrical interconnects can form electrical connections between elements of the electrical circuits as well as to connect the elements of the circuit to external connections. With respect to solar cell connections, generally poles of the cell are electrically interconnected to contacts on the semiconductor for harvesting of the photocurrent. The two poles of the cell can be connected to a plurality of appropriate contacts with an appropriate selected pattern along the surface. The solar cell current collectors are designed also for making an external connection to the cell.

Through an appropriate selection of the layered metals and the amounts of metal, very significant processing advantages can be exploited. In general, it has been found that the metal at a particular location can be heated to form an alloy of the metals, which involved much less energy than the ablation of the metal. Thus, the top layer is selected based on the alloying ability with lower metal. Also, the selection of the amount of metal for the upper layer can be significant. In particular, the amount of the upper metal should be at the most the amount of metal that can form an appropriate alloy with the lower metal based on the amount of the lower metal in the layered material so that effectively the entire quantity of the upper metal is incorporated into the alloy leaving an alloy exposed at that location of the surface. In some embodiments, the composition of the metal layers can be selected such that the top layer forms a low melting eutectic alloy with the metal of the bottom layer. Following the formation of the alloy, the top surface is patterned with regions of alloy and regions with the original metal of the top surface. Based on the selection of metals, selective etching can be used to remove metal at some sections of the pattern while leaving metal at other sections of the pattern. For example, in some embodiments, the alloy as well as the lower metal can be preferentially etched relative to the top metal. In alternative embodiments, the original top metal and lower metal layers can be preferentially etched relative to the alloy.

In selecting the amount of metal in the upper layer, there can be balance of factors. In particular, the upper metal layer should be thick enough that the upper metal layer is not removed at arbitrary locations by etching at a slower etch rate during the etching for the removal of the alloy and lower layer corresponding to the alloy pattern. A particular thickness of the upper layer may also be desirable from the perspective of further processing of the device, such as soldering to the upper layer. On the other hand, it may be desirable to use a smaller amount of the upper metal such that a smaller volume of metal is melted to form the alloy, such as a eutectic alloy. The use of a smaller amount of the upper metal can also reduce the amount of heat needed from the light beam to form the alloy. In summary, the upper metal layer cannot be too thick such that the upper metal at the target locations can form an alloy with the lower metal layer and such that excessive amounts of heat are not needed to form the alloy, but the upper layer should be thick enough such that the etching does not remove portions of the upper layer during etching and a desired amount of metal remains after the conclusion of the patterning process.

In general, the patterning of the metal interconnects is performed by processing the metals to form the alloy of the top metal with the underlying metal at locations where the light beam is scanned across the surface. At these alloyed locations, the top metal is no longer substantially present in its original form. Following the patterning for alloy formation, the top surface has locations with alloy and other locations with the original metal top layer. The alloy generally comprises a substantial fraction of the metal from the lower layer and has etching properties significantly different from the original metal top layer. Due to differential etching properties, in some embodiments, the alloy and lower metal layer can be selectively etched to remove the alloy and metal layer under the alloy while leaving at least a portion of the top layer according to the pattern. In other embodiments, the original top metal and the bottom layer can be selectively etched to leave at least a portion of the alloy layer along with at least some metal below the alloy if present. Through the use of differential etching, the metal can be patterned without ablating the metal.

The spatial resolution of the patterning is a function of the ability to selectively form the alloy along the surface of the metal layers. The process is particularly effective for the formation of moderate resolution interconnect structures for moderate or lower cost applications. In some embodiments, laser systems can be used to scan a laser beam across the surface to effectuate the alloy formation at a relatively rapid rate. The laser beam can be pulsed at an appropriate rate to match the movement of the beam based on the beam width to scan a reasonable pattern across the surface. While a laser beam is a convenient energy source, other light beams or other energy sources can be used if they have sufficient energy to form the alloy. For example, an electric arc or an electron beam can be used to form the alloy at selected locations along the surface.

In appropriate embodiments, light patterning involves the selection of a light wavelength that is reasonably absorbed by the top metal of the metal stack. The heat from the light absorbed by the metal drives the alloy formation that incorporated the top metal layer into the alloy at that physical location along the surface. The light intensity should be low enough such that the metal layer is not damaged significantly, and correspondingly the underlying material is similarly not damaged. Thus, the light fluence can be adjusted to take advantage of the lower thermal load to form the alloy. Multiple passes of the laser can be used along with lower light intensities to obtain more reproducible results, if desired. Also, the alloy forming approach described herein greatly reduces the likelihood of undesirable damage to an underlying semiconductor material relative to ablation approaches as well as reducing the power consumption. The alloy forming approach therefore offers at least two important advantages over ablating the metal to remove the metal.

Specifically, the energy beam is scanned across the surface to form a selected pattern of the alloy through the heating of the top layer of metal. Through pulsing of the light source, e.g., laser, along with scanning the point of contact of the light beam on the surface, any reasonable pattern can be formed. In general, the light beam intersects at an approximately circular or elliptical image, although other shapes can be formed in principal. For example, the scanning of a circular beam image across the surface with incremental displacements can form a rough line of alloy. Once the alloy is formed, selective etching can be performed to form the desired interconnect structure.

Following the formation of the patterned alloy on the surface, the surface is etched to take advantage of the differential properties of the top layer, the bottom layer and the alloy. For example, an etching approach can be selected for which the top layer is resistant to the etch, while the alloy and bottom layer are more susceptible to the etching process. The thickness of the top layer should be large enough that the top layer with its correspondingly slow etch rate is not completely removed during the time in which the alloy layer and the lower layer are etched effectively down to the underlying substrate. A wet etch, a dry etch or a combination thereof can be used. Specific etchants can be selected for some combinations of metals and alloy in which the top metal is not significantly etched while the alloy and lower metal layer are very rapidly etched. In general, a range of etching compositions and dry etching processes is known in the art. It has been discovered that at least in some embodiments the formation of an alloy with a substantial portion of a metal that is easily etched in combination with a metal that is very resistant to the etch results in an alloy that is relatively easily etched. In alternative embodiments, the alloy can be selected to be etch resist for appropriate etchants such that the original top metal layer and bottom metal layer are selectively etched.

The process of patterning the alloy and subsequent etching is successful if the edges of adjacent conductive elements are sufficiently electrically isolated following the etching process such that little if any current flows through short circuit pathways. Furthermore, the desired conductive pathways should be sufficiently intact that the resulting electrical interconnects have low electrical resistivity. The alloy pattern should provide for proper removal of metal to form gaps between spaced apart sections of the adjacent remaining interconnect features. Also, the etching process should be effective to remove any metal at the positions below the selectively etched metal to remove the metal down to the underlying substrate surface without significantly damaging the adjacent metal layers under the intact top metal surface, which can be the original top metal layer or the alloy. Thus, the formation of the alloy and the etching steps should be appropriately selected so that the patterning for alloy formation corresponds with the resulting patterning of the electrical interconnects at the locations at which the alloy was not formed.

Other approaches for laser patterning for forming electrical interconnects involve ablating metal from the structure along the surface to leave behind the desired interconnects. In other words, the metal is removed through ablation where it is desired to remove the metal. A laser ablation approach is described further in U.S. Pat. No. 5,104,480 to Wojnarowski et al., entitled “Direct Patterning of Metals Over a Thermally Inefficient Surface Using a Laser,” incorporated herein by reference. Metal patterning can also be obtained using masking approaches. Masking in combination with electroplating is further described in published U.S. patent application 2008/0210301A to Mulligan et al, entitled “Metal Contact Structure for Solar Cell and Method of Manufacture,” incorporated herein by reference.

In the processes described herein, the layered metals are selected such that the metal of the top surface can be effectively incorporated into an alloy formed with the metal of the underlying layer with a modest amount of energy. In some embodiments, the resulting alloy can be a low eutectic temperature alloy. Eutectic alloys are formed in a ratio of metals that are combined into an alloy with a particular composition that has a particularly low melting point in comparison with the two metals forming the alloy. In some embodiments, the metal of the top layer can form an alloy with an appropriate portion of the lower layer to form a surface alloy of the eutectic mixture if the top layer is sufficiently thin. In general though, a significant property of the resulting alloy is that the alloy has different etching properties relative to the top metal where the alloy is not formed. Some specific alloys of interest include, for example, a nickel-aluminum alloy optionally with small amounts of additional metals, although other potentially useful alloys are known in the art.

In general, the electrically conductive interconnects and the alloy formation process described herein provide a cost effective approach to form a range of devices with a reduction in the use of energy and a rapid and convenient processing format for commercial fabrication. In particular, these approaches are useful for large area applications, with moderate resolution of structures and with significant cost considerations.

In particular, the formation of moderate resolution electrical interconnects on large format semiconductor provide useful substrates for display components. In particular, a semiconductor sheet can be a substrate for the formation of thin film transistors and/or other integrated circuit components. Thus, the thin semiconductor sheets can be large format display circuits with one or more transistor associated with each pixel. The resulting circuits can replace structures formed by silicon on glass processes.

Photovoltaic cells based on silicon, germanium or alloys thereof can incorporate a junction with a p-type semiconductor and an n-type semiconductor. In particular, both poles of the doped semiconductor contacts can be placed on the rear surface of the solar cell for effective harvesting of the photocurrent. The flow of current between current collectors of opposite polarity can be used to perform useful work. The efficiency of the process depends in part on the recombination rate since electrons and holes can recombine before they flow to suitable current collectors. The processes described herein are suitable for the formation of current collectors for photovoltaic cells, such as rear contact solar cells.

### General Description of Structures

The processed structure has a patterned electrical interconnect over the top surface. The electrical interconnect can be characterized, for example, by the pattern, the dimensions of the interconnect material and the spacing between adjacent interconnect structures. The pattern and surface coverage of the interconnect structure generally are selected to correspond with related structure below the metal interconnect such that the metal interconnect provides electrical conduction pathways to access the functionality built into the underlying structure. The thickness of the interconnect structure can be selected to balance various factors, such as electrical resistance, processing efficiency, cost and the like. The underlying structure can comprise a semiconductor that is patterned to form electronic components. The characteristics of the final structure can be related to the structure of several intermediate structures that are patterned during the processing to form the desired structure.

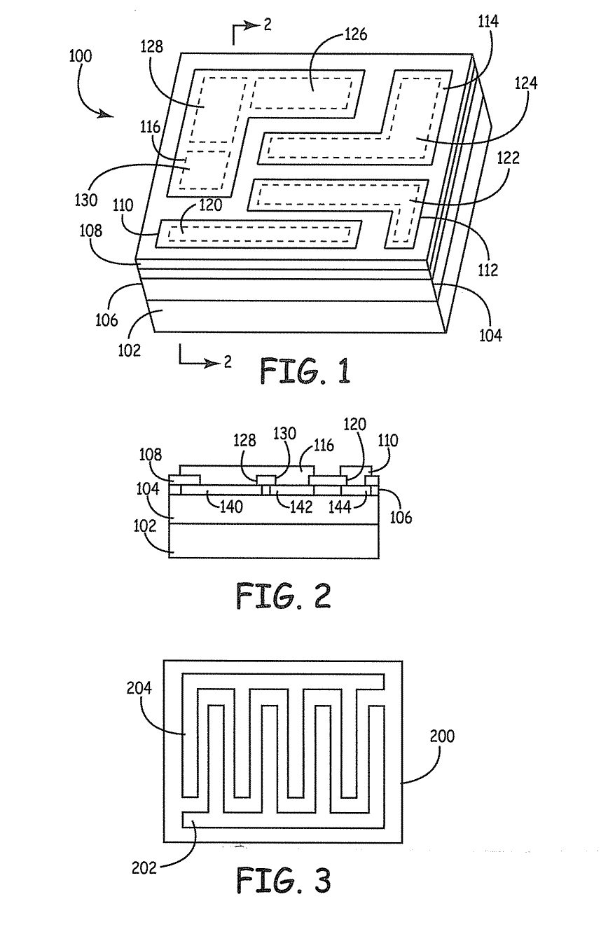

An example of a structure with a patterned electrical interconnect is shown in FIG. 1. In this embodiment, structure 100 comprises a support layer 102, under-layer 104, patterned active layer 106, windowed dielectric layer 108 and metal electrical interconnect features 110, 112, 114, 116. Windows 120, 122, 124, 126, 128, 130 are shown with phantom lines in FIG. 1. A cross section is shown in FIG. 2. Windows 128, 130, 120 respectively expose active elements 140, 142, 144 to electrically conductive elements 116, 110 through dielectric layer 108, as shown in FIG. 2. A specific embodiment for solar cell applications is described in more detail below. The structure can comprise additional layers in addition to the ones explicitly described with respect to FIG. 1.

Support layer 102 is an optional structure that can provide structural support for the overall structure. In some embodiments, support layer 102 can cooperate with functional features of structure 100. For example, for solar cell and display applications, it can be desirable for support layer 102 to be a transparent element, such as a transparent glass, e.g., a silica glass, or a transparent polymer. If support layer 102 is transparent, light can transmit from exterior to the structure to excite a photocurrent that is harvested, or light generated within the structure can be transmitted through the layer for visual observation. In general, support layer 102 can be formed from any reasonable material, such as ceramic materials, polymer materials, metals, or combinations thereof as long as the selected material does not interfere with the function of the structure. Support layer 102 may or may not have the same planar extent as under-layer 104, and support layer 102 can have any reasonable thickness consistent with the function of structure 100. Support layer 102 can comprise a plurality of layers that differ from each other, for example according to composition or the like.

Under-layer 104, if present, generally can support the function of the device, such as through providing material for the patterning of active elements or providing appropriate electrical properties. In some embodiments of particular interest, under-layer 104 comprises a semiconductor material. For example, under-layer 104 can comprise elemental silicon or elemental germanium, optionally with dopants, although other semiconductors can be used, such as gallium arsenide or the like. Elemental silicon is a widely used semiconductor material, and silicon wafers are commercially available, such as single crystal silicon wafers.

Recently technology has been developed for the formation of large area, thin polycrystalline silicon foils. The thin nature of the foils provides for the reduced use of silicon material, and the potential for large area structures can be particularly useful for corresponding large format products, such as optical displays and solar cells. In some embodiments, the foils can have a thickness no more than about 250 microns, in further embodiments no more than about 200 microns, in additional embodiments from about 3 microns to about 150 microns, in other embodiments from about 5 microns to about 100 microns and in some embodiments from about 8 microns to about 80 microns. A person of ordinary skill in the art will recognize that additional ranges of thicknesses within these explicit ranges are contemplated and are within the present disclosure.

In order to reduce the use of silicon in solar cells, thin polycrystalline silicon foils can be desirable to achieve a high efficiency with a modest consumption of materials. In some embodiments, the inorganic foils, e.g., silicon sheets, can have a large area as well as being thin. For example, the foils can have a surface area of at least about 900 square centimeters, in further embodiments at least about 1000 cm², in additional embodiments from about 1500 cm² to about 10 square meters (m²) and in other embodiments from about 2500 cm² to about 5 m². A person of ordinary skill in the art will recognize that additional ranges of surface area within the explicit ranges above are contemplated and are within the present disclosure. For silicon foils and perhaps other polycrystalline inorganic materials, the electronic properties can be improved in some embodiments through the recrystallization of the silicon following the initial formation of the thin silicon layer. A zone melt recrystallization process can be applied to improve the electrical properties, such as carrier lifetimes, of the silicon material.

Elemental silicon or germanium foils, with or without dopants, can be formed through reactive deposition onto a release layer. It may be desirable to have light doping of the layer to increase electron mobilities. The foil can be separated from the release layer for incorporation into a desired device. In particular, scanning reactive deposition approaches have been developed for deposition onto an inorganic release layer. The foils can be deposited, for example, using light reactive deposition (LRD™) or with chemical vapor deposition (CVD), e.g., sub-atmospheric pressure CVD or atmospheric pressure CVD. Reactive deposition approaches can effectively deposit inorganic materials at a significant rate. LRD™ involves the generation of a reactant flow from a nozzle directed through an intense light beam, such as a laser beam, which drives the reaction to form a product composition that is deposited onto a substrate that intersects the flow. The light beam is directed to avoid striking the substrate, and the substrate is generally moved relative the flow to scan the coating deposition across the substrate and an appropriately shaped nozzle oriented appropriately relative to the light beam can scan the coating composition to coat an entire substrate in a single linear pass of the substrate past the nozzle. LRD™ reactive deposition onto a release layer is described generally in U.S. Pat. No. 6,788,866 to Bryan, entitled “Layer Material and Planar Optical Devices,” incorporated herein by reference as well as in published U.S. patent application 2007/0212510A to Hieslmair et al., entitled “Thin Silicon or Germanium Sheets and Photovoltaics Formed From Thin Sheets,” incorporated herein by reference.

CVD is a general term to describe the decomposition or other reaction of a precursor gas, e.g., silanes, at the surface of a substrate. CVD can also be enhanced with plasma or other energy source. CVD deposition can be well controlled to yield a uniform thin film at a relatively rapid deposition rate when performed in scanning mode. In particular, a directed reactant flow CVD has been developed with scanning of the deposition across a substrate surface in an enclosure at a pressure lower than the ambient pressure. The reactant is directed from a nozzle to the substrate, which is then moved relative to the nozzle to scan the coating deposition across the substrate. Atmospheric pressure CVD can also be used to deposit thicker layers at reasonable rates. For silicon films, CVD can be performed on a substrate at or near atmospheric pressure at high temperatures ranging from 600° C. to 1200° C. The substrate holder needs to be appropriately designed for use at high temperatures. CVD deposition onto a porous release layer is described further in published U.S. patent application 2009/0017292 to Hieslmair et al., entitled “Reactive Flow Deposition and Synthesis of Inorganic Foils,” incorporated herein by reference.

Active elements, such as elements 140, 142, 144, are located within patterned layer 106 on or within the surface of under-layer 104. Active elements generally provide the functionality to structure 100, and the active elements are correspondingly generally patterned along the surface of under-layer 104. As shown in FIG. 1, there are 6 active elements with one active element corresponding to each window 120, 122, 124, 126, 128, 130. In further embodiments, there can be 1, 2, 3, 4, 5, 7, 8, 9, 10, 15, 20, 30 or more elements. For example, in display applications, it may be desirable to have thousands of elements corresponding to individual pixels of a display.

In some embodiments, the active elements can correspond with doped regions along the semiconductor sheet represented by under-layer 104. Therefore, patterned layer 106 may not be a distinct layer from under-layer 104, and patterned layer may represent surface modifications along a surface of under-layer 104. The dopant can be introduced by a wide range of techniques known in the art. For example, photo-lithography techniques can be used to perform the patterning, and the dopant atoms can be introduced for incorporation into the semiconductor material. In particular, it may be desirable to incorporate one or more dopants into a silicon/germanium-based semiconductor material, for example, to form n-type semiconductors or p-type semiconductors. Suitable dopants to form n-type semiconductors contribute extra electrons, such as phosphorous (P), arsenic (As), antimony (Sb) or mixtures thereof. Similarly, suitable dopants to form p-type semiconductors contribute holes, i.e., electron vacancies, such as boron (B), aluminum (Al), gallium (Ga), indium (In) or combinations thereof.

Dopant concentrations for semiconductors can be selected to yield desired properties. In some embodiments, the average dopant concentrations can be at least about 1×10¹³ atoms per cubic centimeter (cm³), in further embodiments, at least about 1×10¹⁴ atoms/cm³, in other embodiments at least about 1×10¹⁶ atoms/cm³ and in further embodiments 1×10¹⁷ to about 5×10²¹ atoms/cm³. With respect to atomic parts per million (ppma), the dopant can be at least about 0.0001 ppma, in further embodiments at least about 0.01 ppma, in additional embodiments at least about 0.1 ppma and in other embodiments from about 2 ppma to about 1×10⁵ ppma. A person of ordinary skill in the art will recognize that additional ranges of dopant concentrations within the explicit ranges above are contemplated and are within the present disclosure.

A suitable approach for dopant introduction consistent with the processes described herein for metal patterning involves a laser drive-in of dopants to pattern the layer with selected dopants at desired locations. The dopant is deposited across the substrate surface, and an intense light beam is scanned across the surface to form the pattern. A p-type dopant and an n-type dopant can be sequentially deposited according to a desired pattern. Laser patterning of dopant deposition is described further in copending patent application filed on the same day as the present application to Srinivasan et al., entitled “Back Contact Solar Cells With Effective and Efficient Designs and Corresponding Patterning Processes,” incorporated herein by reference (hereinafter the “copending Srinivasan application”).

It may be desirable to have a windowed dielectric layer 108 to decrease the chance of undesirable interactions between functional elements to have stable performance of the ultimate device. The dielectric material is electrically insulating. In general, suitable dielectric materials for appropriate applications include, for example, metal/metalloid oxides, metal/metalloid carbides, metal/metalloid nitrides, polymers, combinations thereof, or mixtures thereof. If the dielectric is adjacent a semiconductor layer comprising silicon and/or germanium, it can be convenient to use a corresponding silicon/germanium composition for the dielectric. Thus, for a silicon-based photovoltaic, it may be desirable to incorporate a silicon oxide, a silicon nitride, a silicon oxynitride, a silicon carbide, a silicon carbonitride, blends thereof, or combinations thereof, as a dielectric adjacent the silicon-based semiconductor. An inorganic dielectric material can be deposited by CVD or other suitable approach. Polymers can also be a desirable dielectric since they can be deposited using polymer deposition approaches from a melt or a solution, such as extrusion, spin coating, spray coating, knife coating, casting, molding or the like. Suitable polymers can comprise, for example, polycarbonates, vinyl polymers, fluoropolymer, such as polytetrafluoroethylene, polyamides, copolymers thereof, mixtures thereof and the like. In some embodiments, the dielectric can comprise an inorganic layer and a polymer layer, for example, with the current collector deposited onto the polymer.

The windowed dielectric layer can be formed, for example, using conventional photolithography or the like. Thus, the dielectric can be deposited through corresponding windows in a photoresist, or a layer of dielectric can be selectively etched using patterned resist material. Approaches for window formation are described in the copending Srinivasan application. Specifically, in an improved etching approach of the Srinivasan application, a polymer etch-resist is ablated with a laser or other focused energy beam prior to performing an etching step to form the windows. The polymer etch resist can then be removed, or the polymer etch resist can be maintained as a portion of the dielectric material. In another ablation approach, the dielectric is ablated with a energy beam, such as a laser, at the locations selected for window formation. The ablation conditions are selected such that the underlying material below the dielectric is not significantly damaged. Laser-fired contacts are described for solar cell formation in U.S. Pat. No. 6,982,218 to Prue et al., entitles “Method of Producing a Semiconductor-Metal Contact Through a Dielectric Layer,” incorporated herein by reference. In the laser-fired contact approach, a laser is used to punch metal from a current collector through the dielectric layer to make an electrical contact between the metal and a doped contact as the active element below the dielectric layer. A window is inherently formed during the laser-fired contact formation. In a selected approach for window formation, the location and size of the windows can be selected according to the functional elements. Specifically, a window generally is aligned with each functional element. In some embodiments, the windows can be somewhat larger, approximately the same size or somewhat smaller than the corresponding functional element.

As described in the copending Srinivasan application, for solar cell applications, the windows are generally at least somewhat smaller than the corresponding functional elements, and this relationship of the structures can be desirable also for circuit applications. In particular, it can advantageous for the window to have an area no more than about 80% of the area of a corresponding functional element, in further embodiments from about 5% to about 75% of the area and in additional embodiments from about 10% to about 70% of the area of the corresponding functional element. Similarly, it is generally desirable for the metal interconnects to have a spatial extent along the surface greater than the windows. In some embodiments, the area of a metal interconnect is generally at least a factor of 1.2 greater than a corresponding window, in further embodiments at least about 1.5 and in additional embodiments from about 2 to about 100 times the area of corresponding window. A person of ordinary skill in the art will recognize that additional ranges of area ratios within the explicit ranges above are contemplated and are within the present disclosure.

Metal electrical interconnect features 110, 112, 114, 116 comprise a patterned layer(s) of metal. In some embodiments, the metal has at least two layers, although generally the top layer can be removed if desired at the conclusion of the patterning. The patterning generally is performed to have a portion of a metal contact aligned with the windows through the dielectric for appropriate embodiments. During the processing, metal is removed to form electrically insulating barriers between metal interconnects. The metal layer(s) of the electrical interconnects should be thick enough to provide appropriate electrical conductivity for the expected current. In some embodiments, the average total metal thickness is from about 25 nanometers (nm) to about 30 microns, in further embodiments from about 50 nm to about 15 microns, in other embodiments from about 60 nm to about 10 microns and in additional embodiments from about 75 nm to about 5 micron.

If the metal layer has a layered structure, the top metal layer can comprise an original top metal layer that is etch resistant or an etch resistant alloy formed from an original top metal layer and an under-layer. In some embodiments, the top metal layer can have a thickness less than a lower metal layer since the top metal layer may be incorporated into an alloy with the bottom layer during the processing, as described in the following section. If the top layer is thicker, a greater amount of energy is consumed in forming the alloy, so a thinner top layer can reduce energy consumption during processing. In some embodiments, the top layer has a thickness from about 5 nm to about 1 micron, in further embodiments from about 8 nm to about 800 nm, and in additional embodiments form about 10 nm to about 500 nm. A person of ordinary skill in the art will recognize that additional ranges of total metal thickness from the previous paragraph and top metal layer thickness are contemplated and are within the present disclosure. In principle, the metal interconnect can have greater than two layers, such as three layers, four layers or more than four layers if desired. Also, all of the metal interconnects within a structure may or may not have the same number of metal layers.

The spacing between adjacent metal interconnect elements that are electrically isolated form each other can be a significant feature with respect to the resulting structure. In the processes described herein, the spacing is the result of an energy driven alloy step followed by an etch. The dimension of the spacing is determined by the processing steps used to form an alloy between a top metal layer and a lower metal layer. The etching process may leave traces of metal within an etched trench, which are not considered as part of the spacing evaluation. In some embodiments, the average spacing between adjacent edges of conductive elements can be at least about 5 microns, in further embodiments at least about 8 microns and in other embodiments at least about 10 microns. A person of ordinary skill in the art will recognize that additional ranges of average spacing within the explicit ranges about are contemplated and are within the present disclosure.

The etching process should remove a sufficient amount of metal from the trench between adjacent sections of electrical conductive metal elements that the electrical resistance is sufficient to isolate the metal elements, and effective electrical isolation has been achieved, as described further in the examples below. The processes are suitable for forming fine structures of the metal interconnect, and metal interconnects can be formed with linear segments having a selected width, an appropriate length and turns to form the overall pattern. In some embodiments, the current collectors can be patterned to form large area circuits. For example, two current collectors can be formed as interlaced opposite poles of a circuit covering areas at least about 1000 mm², in further embodiments, at least about 2500 mm², in additional embodiments at least about 5000 mm². For solar cell applications, some appropriate circuits sizes can be roughly rectangular with a dimension along each edge independently from 50 mm to about 600 mm. A person of ordinary skill in the art will recognize that additional ranges of area and linear dimensions within the explicit ranges above are contemplated and are within the present disclosure.

In general, most metals provide a desired degree of electrical conductivity. For some applications, cost is a significant consideration in selecting a metal, and process considerations can further influence metal selection. As described below, for the processing approach described herein, a structure can be formed having at least two metal layers. In some embodiments, the top metal layer can be selected based on the ability to resist etching under selected etching conditions, which can be a wet etch or a dry etch. The lower metal layer is selected in combination with the original top metal layer such that the original top metal forms an alloy with the lower metal and such that the lower metal is etched efficiently under conditions where a top layer, the original top metal or the alloy, is not etched or etched slowly. The alloy is similarly selected for its appropriate etching properties. In some embodiments, the alloy etches efficiently under conditions where the top layer is not etched or etched slowly and where the bottom layer is also etched efficiently.

Aluminum and alloys thereof are convenient metal materials for the lower metal layer for the layered metal structures. In particular, aluminum and alloys thereof are highly conductive, relatively inexpensive, form alloys with other convenient metals and are easily etched with reasonable etchants that do not damage desirable dielectric layer or semiconductor layers. Furthermore, aluminum has a relatively low melting point, which may lower the amount of energy for alloy formation with the heated sections of the upper layer. In particular, aluminum, optionally alloyed with 0.1 to 5 weight percent silicon, can be used in some embodiments. Other appropriate lower metals include, for example, copper (Cu) and silver (Ag).

As noted above, the upper metal is selected based on its alloying with the lower metal. The upper metal can be an alloy itself. Other considerations with respect to selecting the upper metal include, for example, sufficient absorption of a convenient light wavelength to allow for processing as described further below. With an aluminum base metal in the lower layer, suitable upper layers include, for example, nickel, titanium, molybdenum and alloys of these metals. Nickel is particularly convenient since it is lower in cost, is corrosion resistant and is a good metal for soldering to the resulting metal interconnect. Nickel vanadium alloys are described in the examples below. In addition, nickel forms a low eutectic melting alloy with aluminum, which may also lower the energy consumption for alloy formation. With a copper lower layer, a suitable upper layer includes, for example, zinc, which forms a brass alloy with copper. Depending on the selection of etchants, the zinc or the brass can be selectively etched along with the copper, which is more easily etched than either the zinc or the brass.

### Patterning Process

The energy beam, e.g., light-based, patterning process described herein provides an efficient and cost effective approach to forming conductive metal interconnects for various applications, such as providing electrical connections for semiconductor based devices. In some embodiments, a light beam, which can be conveniently supplied by a laser, can be used to scan across a surface with a layered metal structure. The light wavelength and the compositions of the metal layers are selected such that the top metal layer absorbs the light sufficiently to heat the structure and form an alloy between the top metal layer and the under-layer of metal. Following light patterning to form the alloy pattern, the structure can be selectively etched to remove the metal at the selected locations based on where the alloy was formed. The process is very versatile with respect to pattern selection, and the process can be fast and efficient.

With respect to forming the electrical interconnects, the underlying structure can be formed based on the desired function of the device. Two specific applications are described below. As noted above, the underlying structure may or may not be windowed. To form the metal electrical interconnects, a layered metal structure is first formed. The layered metal structure is then patterned using a light beam to form a pattern of alloy along the top surface. The patterned layered structure is then selectively etched, e.g., to remove the alloy and the metal below the alloy to form the metal interconnects. Specifically, a trench between sections of intact metal is then formed according to the alloy pattern to have electrically insulating gaps between neighboring electrically conductive pathways.

The metal layers can be deposited, for example, using conventional techniques, such as sputtering and evaporation. In sputtering, ions are formed using high electric fields in a vacuum chamber with a low pressure of an inert gas, such as argon. The ionized inert gas is accelerated to a target at a cathode, in which the target is formed of the desired metal to be deposited. The energetic collision of the inert ion with the target at the cathode results in the ejection of the metal, which then is propelled to the substrate based on the electric field where it is coated onto the surface. In evaporation, the selected metal from a source is heated to generate an appropriate vapor pressure such that the metal is coated onto an appropriately positioned substrate.

In light based embodiments, any reasonable light source can be used, but lasers are a convenient high power light source. Similarly, the light wavelength can be selected such that the top metal layer has a reasonable absorption of the light so that the light can heat the top layer and drive the alloy formation. In particular, transition metals absorb well in near IR, and for transition metal top layers a near IR layer can effectively form the alloy without adding extra heat throughout the entire structure. However, visible and ultraviolet wavelengths can also be used for appropriate metals. An inexpensive laser source includes, for example, a diode pumped fiber laser. A SPI™ 20 watt fiber laser has a wavelength of 1064 nm. The SPI™ laser also has a pulse width of 12 nanoseconds (ns) to 50 ns, and a pulse frequency of 25 to 500 kHz.

In general, a significant parameter is the light pulse energy density with respect to supplying sufficient energy for alloy formation. In general, the pulse energy density can be matched roughly to the properties of the metal including, for example, the thickness of the top metal layer and the melting points of the metals and the resulting alloy. In general, reasonable pulse energy densities can be from about 0.25 to about 25 Joules per square centimeter (J/cm²), in further embodiments from about 0.5 to about 20 J/cm² and in other embodiments from about 1.0 to about 12 J/cm². A person of ordinary skill in the art will recognize that additional ranges of pulse energy densities within the explicit ranges above are contemplated and are within the present disclosure.

In general, the line width can be adjusted using the optics to select the corresponding light spot size at least within reasonable values. The line widths of the alloy correspond to the spot size. The light intensity is generally not uniform across the light beam, but the beam shape can be adjusted to be Gaussian or flat-top type depending on the optics arrangement. Pulse frequencies in some embodiments can be from about 5 kilohertz (kHz) to about 5000 kHz, in further embodiments from about 10 kHz to about 2000 kHz, and in additional embodiments from about 25 kHz to about 1000 kHz. Scanning speeds can range in some embodiment from about 0.1 to about 15 meters per second (m/s), and in further embodiments from about 0.25 to about 10 m/s, and in other embodiments from about 1 to about 10 m/s. A person of ordinary skill in the art will recognize that additional ranges of pulse frequencies and scanning speeds within the explicit ranges above are contemplated and are within the present disclosure.

Based on a particular spot size, the scan speed of the light beam across the substrate can be correlated with pulse frequency so that adjacent pulses may overlap to a selected degree to provide a contiguous processed structure with alloy formation. In some embodiments, adjacent spots can be spaced to not overlap if multiple passes of the laser over the pattern provide eventual overlap to form a contiguous alloyed pattern. Whether or not adjacent pulses of a single scan overlap, it has been found that in some embodiments it is desirable to use a lower pulse energy density and scan over the line or other patterned shape a plurality of times. A multiple pass approach can result in less damage to the substrate and a more even line. In some embodiments, it may be desirable to provide two passes, three passes, four passes, five passes or more than five passes of the light beam over the same pattern of the surface to obtain more desirable results.

Since the intersection of the light beam with the substrate is generally roughly circular, some overlap can be desirable to get a rough edge of the alloy structure, although multiple passes over the same region can smooth out gaps from adjacent pulses. For convenience, we define a light spot as a circle along the surface with 95 percent of the light power included within the perimeter. The light pulse rate and scanning speeds can be selected such that the centers of the image of adjacent light pulses are displaced from each other in the range from 0.1 to about 1.5 times the light image diameter, in further embodiments from about 0.2 to about 1.25 times the light image diameter and in additional embodiments from about 0.25 to about 1.1 times the light image diameters. A person of ordinary skill in the art will recognize that additional ranges within the explicit ranges above are contemplated and are within the present disclosure.

As described in the Examples below, sharp turns in the pattern can result in damage or other undesirable results. In particular, the scan speed is reduced during the turn, but the laser pulsed rate remains the same to provide for stability of the laser. However, if the pulse rate remains constant and the scan speed slows, the laser pulses overlap more, and undesirable effects can result. It has been found that angular turns for straight segments can be performed with less slowing of the scan speed. In particular, the turns can be selected to be at least about 95 degrees, in some embodiments at least about 98 degrees and in some embodiments at least about 100 degrees. The angle is measured as an internal angle such that a sharp right angle turn is 90 degrees and a less sharp turn has a larger angle. A person of ordinary skill in the art will recognize that additional ranges of angles within the explicit ranges above are contemplated and are in the present disclosure. A plurality of these angles straight segment turns can be connected to form the desire overall turn. For example, a u-turn can be accomplished with 5, 6, 7, 8, 9, 10 or more straight line turns. A u-turn with connected straight segments connected to form the turn is described in the examples. The straight segments generally comprise multiple laser pulses, such as at least four laser pulses. To provide for longer straight segments to achieve more uniform results, an initial turn can be away from the ultimate turn direction so that the corner can cover a larger area with desirably long straight line segments and angles within desired ranges.

The light beams can be scanned across the substrate surface using commercial scanning systems or similarly designed custom systems. Generally, these systems comprise optical elements to scan a laser beam to a selected location. Position detectors useful in optical scanning systems are described further in U.S. Pat. No. 6,921,893 to Petschik et al., entitled “Position Sensor for a Scanning Device,” incorporated herein by reference. Control systems useful for scanners are described in U.S. Pat. No. 7,414,379 to Oks, entitled “Servo Control System,” incorporated herein by reference. Commercial scanning systems or galvanometers are available form Scanlab AG (Germany) and Cambridge Technology Inc. (MA, USA). In alternative embodiments, an electric arc can be scanned across a surface for selected local heat delivery can be adapted using a system such as described in U.S. Pat. No. 5,481,084 to Patrick et al., entitled “Method for Treating a Surface Such as a Metal Surface and Producing Products Embodying Such Including Lithoplate,” incorporated herein by reference. An electron beam can be similarly used as an electric arch to supply the energy for alloy formation.

In general, wet etching and dry etching approaches are known for the selective etching of materials. Wet etching approaches generally involve liquids. The liquids and/or dissolved reactive compositions perform the wet etching through a reaction with the metal. In general, dry etching uses energetic beams, such as plasma or the like to etch a material. For example, halogen ions, such as chlorine, can be used to etch a metal, and inert ions, such as argon ions, can be used to sputter etch a metal. An approach for the selective etching of transition metals is described in U.S. Pat. No. 5,814,238 to Ashby et al., entitled “Method for Dry Etching of Transition Metals,” incorporated herein by reference.

Also, wet etching approaches generally can provide desired amount of etching differential for some reasonable metal layers that can be convenient in some embodiments. A great deal of public information is available relating to wet etchants for metals. In general, wet etchants can comprise acids, bases and/or other reactive compositions. This information can be supplemented by empirical evaluation, and specific examples are discussed in the Examples below.

As noted above, the top metal layer is selected to provide an etch resist layer. For an aluminum base layer, suitable top metal layers include, for example, nickel, titanium, molybdenum, and alloys thereof. The aluminum layer and aluminum alloys can be etched with bases, such as KOH and NaOH. Nickel and molybdenum are etched slowly or not at all by hydroxide base etchants, and these metals absorb in the rear IR. More specifically, the etching can be performed, for example, with KOH 25% at 40 degrees C. Titanium is etched slowly by KOH. Furthermore, aluminum can be etched with a solution of H₃PO₄:HNO₃:CH₃COOH:H₂O at a weight ratio of 16:1:1:2 at 50° C., and titanium is negligibly etched under these conditions. Therefore, an aluminum or aluminum alloy bottom layer covered with nickel, titanium, molybdenum or alloys thereof form suitable metal layers for the alloy-based patterning approach described herein. In alternative embodiments, copper or an alloy thereof can be used as the lower metal and zinc or an alloy thereof can be used as the top metal. The patterning then comprises the formation of a brass alloy at selected locations along the surface. In these embodiments, a moderate acid can be used as a selective etchant for zinc and copper while leaving the brass substantially intact, and FeCl₃ can be used as a selective etchant for brass as well as the copper while leaving the zinc substantially intact. Thus, for this system, either the alloy or the original top metal layer can be subjected to selective etching.

To perform wet etching, the patterned structure is contacted with the wet etchant to remove the etched material. In general, it is desirable to select etchants that perform the etch relatively quickly, which is consistent with the small thickness dimension of the metal layers. It generally is desirable to avoid excessive etching so that the edges of the etched trench are not etched more than desired, although the etch should be performed for a long enough period of time that the etched trench provides good electrical isolation between adjacent elements of the electrical interconnect. In some embodiments, the etching process can be performed for a period of time from about 10 seconds to about 1 hour, in further embodiments from about 20 seconds to about 30 minutes, and in additional embodiments from about 30 seconds to about 15 minutes. A person of ordinary skill in the art will recognize that additional ranges of times within these explicit ranges are contemplated and are within the present disclosure. After the etching is complete, the substrate surface can be removed form contact with the etching solution and washed and/or dried in preparation for further processing.

In general, the resulting electrical interconnects are eventually connected to an external circuit. A nickel top surface layer is suitable for providing a solder connection to the substrate. In further embodiments, alternative approaches such as welding. In some embodiments, the top metal layer can be removed. For example, a non-selective dry etching approach can be used to remove the top layer assuming that the top layer is sufficiently thinner than the bottom layer that the top layer can be removed with only a modest portion of the lower layer removed based on the etching time. In some embodiments, a selective wet etch can be used to remove the top metal layer.

### Solar Cell Applications

The processes and structures described herein can be effectively applied for solar cell electrical contacts. In general, metal interconnects are patterned on one or both surfaces of the solar cell. The light receiving surface is generally referred to as the front surface, and the opposite surface is termed the rear surface. There are a large number of solar cell designs and corresponding material used in these systems. In some embodiments, the solar cells have a crystalline silicon layer that absorbs that light and generates electron-hole pairs. For these crystalline silicon solar cells, doped regions along the surface of the silicon are used as contacts that facilitate the harvesting of the photocurrents. The electrical interconnects are used to connect the doped contacts with an external circuit.

P-doped and n-doped contacts form the opposite poles of the solar cell. In some embodiments, one polarity of doped contacts is placed along the front surface and the opposite polarity of doped contacts is placed along the rear surface. Some effective designs involve the placement of both polarities of doped contacts along the rear surface of the cell. In general, the metal interconnects described herein can be effectively used for either design of solar cell.

Solar cells can be formed on silicon wafers cut from ingots of single crystal silicon. However, to reduce the cost of solar power, it can be desirable to reduce the amount of silicon in a solar cell. Techniques have been developed for the formation of polycrystalline silicon foils, as described above. Due to the thinness of the foils, these foils can be effectively formed into efficient rear contact solar cells with reduced consumption of silicon.

In general, the opposite polarity rear contacts are interspersed for effective current collection. A current collector pattern is then designed to connect the contacts of the same polarity in electrical isolation from contacts of the opposite polarity to avoid a short circuit. The approaches described herein are well suited for forming current collectors for rear contact solar cells. Some embodiments of rear contact solar cells are described further in published U.S. patent application 2008/0202576A to Hieslmair, entitled “Solar Cell Structures, Photovoltaic Panels and Corresponding Processes,” incorporated herein by reference. In some embodiments, the location of the contacts can be effectively selected in real time based on the particular properties of a silicon substrate, and the laser scanning approaches described herein are adaptable to use with dynamic positioning. The dynamic selection of electrical contacts is described further in published U.S. patent application 2008/0202577A to Hieslmair, entitled “Dynamic Design of Solar Cell Structures, Photovoltaic Modules and Corresponding Processes,” incorporated herein by reference.

A rear connected solar cell 200 is shown schematically in FIG. 3 with two interdigitated current collectors 202, 204 of opposite polarity. Each current collector 202, 204 are in contact with appropriate doped contacts along the rear surface of the solar cell. Generally, there is a dielectric layer with windows that provide a connection between the metal interconnect and the contact. The formation of a rear contact solar cell structure with doped-contacts and dielectric layers well suited for the introduction of electrical interconnects as described herein is described further in a copending patent application filed on the same day as the present application to Srinivasan et al., entitled Back Contact Solar Cells and With Effective and Efficient Designs and Corresponding Patterning Processes,” incorporated herein by reference.

### Electronics Applications

As noted above, the electrical interconnects and processes for forming patterned metal electrical connections described herein can also be effectively used for electronics applications with moderate resolutions. Also, thin semiconductor sheets can be a versatile substrate for the formation of circuits for displays as well as other integrated circuit structures. For example, the thin silicon/germanium semiconductor foils described above can be further processed with photolithographic techniques and optionally along with other patterning approaches such as printing type technologies. In particular, a sheet of transistor elements, e.g., thin film transistor (TFT) elements, can be formed that can used for the formation of reduced thickness display devices. The metal patterning approaches herein are suitable for the large area semiconductor structures.

In general, thin silicon/germanium-based semiconductor sheets can be deposited onto a permanent substrate or over a release layer on a temporary substrate. The sheet can be patterned to form transistor or other circuit structures. The metal interconnects can then be used to provide appropriate electrical connections to provide for the designed functionality. The formation of thin film transistors using photolithographic techniques from a thin semiconductor film is described further in U.S. Pat. No. 6,787,806 to Yamazaki et al., entitled “Semiconductor Thin Film and Method of Manufacturing the Same and Semiconductor Device and Method of Manufacturing the Same,” and U.S. Pat. No. 7,115,902 to Yamazaki, entitled “Electro-Optical Device and Method for Manufacturing the Same,” both of which are incorporated herein by reference.

With respect to patterning, dopant can be introduced to thin surface areas along the sheet. These domains can be formed using a printed dopant with heat/oven based, a laser-based or similar dopant drive-in. Additional layers can be built up over the semiconductor sheet. These structures can be formed using conventional semiconductor deposition processes, such as photolithography with photoresist and surface based deposition approaches, such as CVD, PVD and the like. Furthermore, spin-on-glasses based on silicates, siloxanes or silsesquioxanes are commercially available from Filmtronics, Inc. In some embodiments, semiconductor inks can be used to deposit semiconductor precursors that can be processed into silicon/germanium-based semiconductor in pure form or with dopants. Functional inks can be used to deposit the functional electronic components onto the semiconductor sheet. Functional inks based on doped silicon nanoparticles are described in published U.S. patent application 2008/0160265 to Hieslmair et al., entitled “Silicon/Germanium Particle Inks, Doped Particles, Printing and Processes for Semiconductor Applications,” incorporated herein by reference. These functional inks can be deposited using any reasonable printing approaches, such as ink jet printing. Printing approaches can be fast and less expensive approaches in comparison with photolithography and related deposition approaches while printing can achieve moderate resolution using existing technology that is expected to further improve. Also, these functional inks can be used to form semiconductor structures using lower temperature processing than conventional processing approaches. The substrates and release layers can be selected to be compatible with the cure temperatures for the ink.

A display incorporating the thin film transistors can be a small, inexpensive display for e-paper, or a larger display for various uses. Photolithography techniques for the formation of TFTs for display applications are described further in U.S. Pat. No. 6,759,711 to Powell, entitled “Method of Manufacturing a Transistor,” incorporated herein by reference.

### EXAMPLES

### Example 1

### Metal Patterning Based on Alloy Formation

This example describes a non-photolithographic process for patterning shapes in a metal layered structure on a silicon substrate covered with a dielectric layer.

A substrate was prepared by initially depositing a silicon oxide coating onto a commercially obtained single crystalline silicon wafer using PECVD. Nitrous oxide and silane gases were pumped into a 650 milliTorr reaction chamber at 1400 sccm and 400 sccm, respectively. The plasma was created in the reaction chamber with radio frequency excitation at 40 W. The resulting silicon oxide layer was 0.5 μm thick. The thickness can be evaluated using the deposition conditions and verified using scanning electron microscopy.

The aluminum and nickel-alloy layers were subsequently deposited using sputtering. The sputtering process was performed using a Perkin Elmer 4450 sputtering system (Perkin Elmer, Waltham, Mass.) in which an inert carrier gas was ionized and accelerated by an electric field to the metal target, which was either an aluminum metal target or nickel alloy target The sputtering resulted in the relatively uniform deposition of metal onto silicon oxide layer on the wafer surface. The sputtering process was initially performed with an aluminum target and then repeated using a metal target comprising nickel alloy with 7% vanadium. The resulting aluminum layer was 1 μm thick, and the resulting nickel layer was 150 nm thick.

The substrate with the two metal layers was patterned by sweeping a laser beam in straight lines across the surface to generate an aluminum-nickel alloy at the locations where the laser beam contacts the surface. The scanning system used a ScanLabs Galvo™ scanner to direct the beam to the surface. A 20 watt diode pumped fiber laser (SPI Lasers, UK) with a center wavelength of 1064 nm was used to generate the laser beam. The infrared light from the laser beam heated the substrate's surface and form the alloy. The laser was pulsed at 65 KHz with an energy density of 11-14 J/cm². The scan head (ScanLab America, Inc., Naperville, Ill.) swept a lattice pattern across surface at 2-3 m/s. The resulting line was believed to be composed of Al₃Ni:V and was between 46-52 μm wide as measured from the scanning electron micrographs.

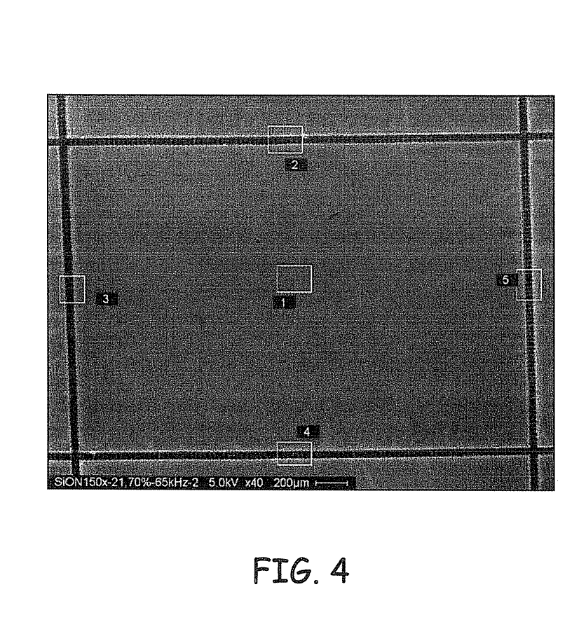

The aluminum-nickel alloy and the aluminum below the alloy were then etched with KOH, leaving only the unalloyed nickel covered aluminum. The etching process was performed by placing the substrate in a bath of 25% KOH for about 3 minutes. The bath was maintained at 40° C. and the concentration gradient of the solution was reduced by either stirring or gas bubbling. Etching resulted in a lattice pattern isolating rectangular conducting regions. The resulting nickel covered aluminum regions are completely isolated from each other, as shown in FIG. 4.

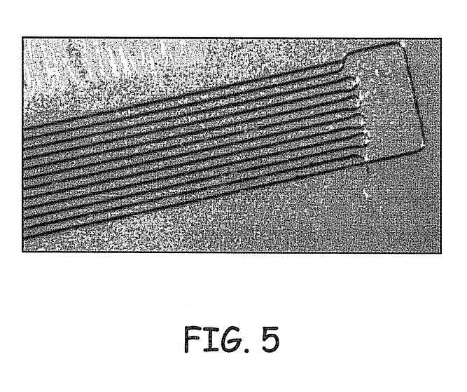

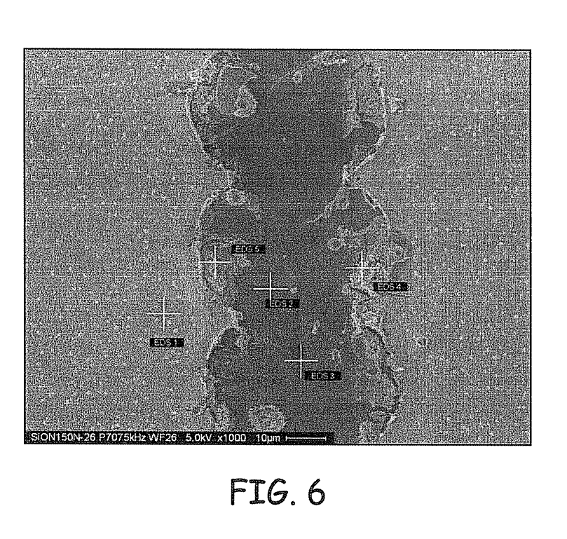

The above process was used to produce a device pattern with turns in the pattern as shown in FIG. 5. An expanded view of the corners is shown in FIG. 6. As shown in FIG. 6, the straight-line portions of the device pattern show a clean etch; there is a clear isolation between abutting nickel-covered aluminum regions and the etch path does not show damage to the underlying wafer.

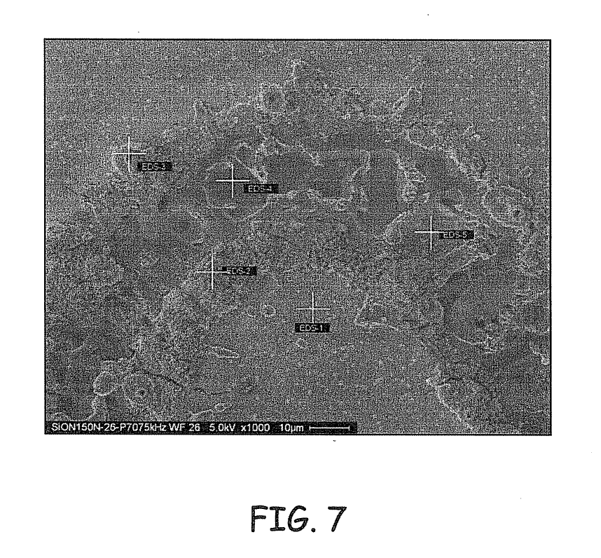

On the other hand, as shown in FIG. 7, the u-turn portions of the device pattern show some damage to the silicon wafer, fused metal, and shorts between the adjacent conducting regions on the wafer. In order to make u-turns in the device pattern during the rastering process, the speed of the scanner had to be slowed. However, the laser maintained its repetition rate when slowed and, therefore, resulted in overlapping laser spots. The overlapping laser spots were responsible for the damage shown in FIG. 7.

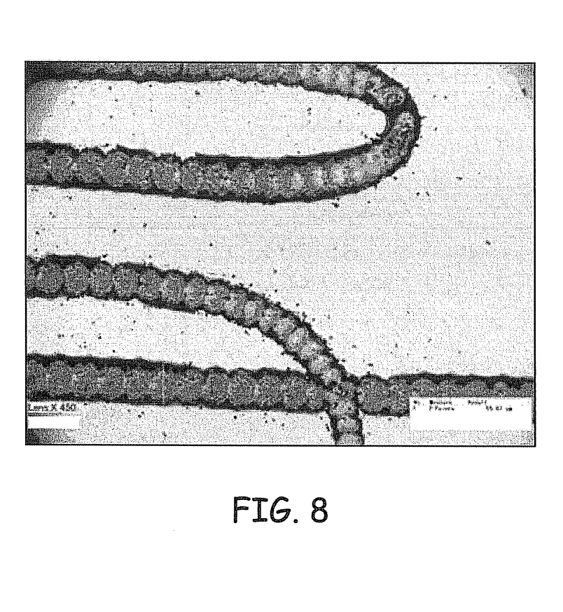

One method used to avoid the damage in the u-turn regions was to scan a u-turn pattern using multiple straight-line segments. Using a multi-segmented design allowed the scan speed to be more closely maintained and, therefore, damage to substrate was avoided. FIG. 8 shows a u-turn segment comprised of five linear segments in which the initial turn was away from the ultimate turn direction such that longer straight segments could be used to form the turn. The u-turn section shows clear isolation between abutting nickel-covered aluminum regions and there is no visible damage to the underlying wafer.

### Example 2

### Metal Patterning with Reduced Peak Power

This example describes a non-photolithographic process for creating a pattern for a metal structure on a layered silicon substrate consisting of a silicon wafer, a silicon oxide layer, an aluminum layer, and a nickel layer.

The substrate was prepared as described in Example 1.

The substrate was patterned by scanning a laser beam across the substrate's surface to generate an aluminum-nickel alloy at locations heated by the laser beam. The rastering process used is described in example 1 with slight modification. The peak power of the pulse was reduce by operating the laser at 60% power using a 78 KHz repetition rate and wave form 26 according to the laser settings. The laser was rastered across the substrate's surface at 3 m/s. The resulting device pattern was similar to that shown in FIG. 5.

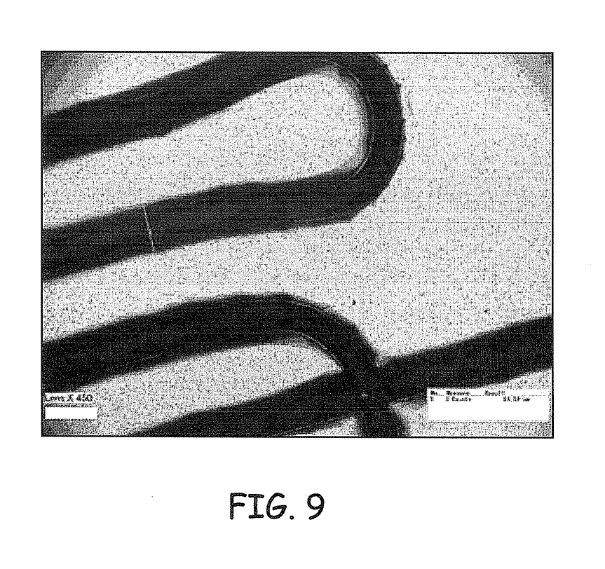

The aluminum-nickel alloy and any exposed aluminum were etched, leaving only the unalloyed nickel covered aluminum. The substrate was etched as described in Example 1. The metal interconnect pattern obtained in this example showed improved results over the structure obtained according to the method used in Example 1. FIG. 9 shows only slight damage in the u-turn region and intersection. The use of multiple straight-line segments for the turns as described in Example 1, can also be used to reduce damage in this context. The straight-line segments show clean etching and separation between abutting nickel-covered aluminum regions.

### Example 3

### Metal Patterning With a Multi-Pass Approach

This example describes a non-photolithographic process for creating a pattern of a metal structure on a silicon nitride layer over a silicon substrate with improved patterning resulting from the passing of a laser over a pattern multiple times to form an alloy of a nickel layer on an aluminum layer.

The substrate was prepared as described in example 1 except that a silicon nitride dielectric layer was placed over the silicon wafer. The silicon nitride layer was deposited using PECVD with NH₃ as a replacement for N₂O reactant. The silicon nitride had a thickness of 65 nm.

The substrate was patterned over a roughly 1 square centimeter area by sweeping a laser across the substrate's surface to generate an aluminum-nickel alloy. The rastering process used is described in example 1 with slight modification. The peak power of the pulse was reduced by operating the laser at 60% power at a 250 KHz repetition rate. The peak power and fluence levels were 1.92 KW and 2.44 J/cm², respectively. The laser was rastered across the substrate's surface at 3 m/s. The substrate was patterned with the laser rastering three times over the same pattern prior to etching. The device pattern was similar to that shown in FIG. 5.

The aluminum-nickel alloy and any exposed aluminum were etched, leaving only the unalloyed nickel covered aluminum. The substrate was etched as described in example 1. The device pattern obtained showed improved results over the methods described in examples 1 and 2. FIG. 10 shows clean etching in the straight segments, the u-turn segments, and the intersection. The nickel covered aluminum sections are electrically isolated and there are no shunted paths or damage to the underlying silicon nitride layer.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What we claim is:

1. A structure comprising a substrate and an electrically conductive material forming a pattern on the surface of the substrate wherein the electrically conductive material has a first layer adjacent the substrate comprising a first metal and a second layer on the first layer comprising a second metal different from the first metal, wherein a spacing between at least some adjacent segments of the pattern is at least about 5 microns, wherein the first metal and the second metal can form an alloy with each other and wherein the relative amounts of the first metal and the second metal provide for the incorporation of the second metal into the alloy with at least a portion of the first metal.

2. The structure of claim 1 wherein the first metal comprises a metal selected from the group consisting of Al, Cu, Ag, Au, and alloys thereof.

3. The structure of claim 1 wherein the second metal comprises a metal selected from the group consisting of Ni, Ti, Mo, Zn and alloys thereof

4. The structure of claim 1 wherein the first metal comprises aluminum and the second metal comprises nickel.

5. The structure of claim 1 wherein the first layer has a thickness from about 25 nm to about 30 microns.

6. The structure of claim 1 wherein the second layer has a thickness from about 5 nm to about 1 micron.

7. The structure of claim 1 wherein the substrate comprises an inorganic semiconductor.

8. The structure of claim 1 wherein the substrate comprises silicon.

9. The structure of claim 1 wherein the electrically conductive material forms a current collector for a circuit covering an area of at least about 1000 mm².

10. The structure of claim 1 wherein the electrically conductive contact is electrically connected with a functional element below a dielectric layer through windows covering no more than about 80% of the area of the functional element.

11. A photovoltaic structure comprising the structure of claim 1.

12. A structure comprising an inorganic substrate and an electrically conductive layer on the substrate wherein the electrically conductive layer comprises first sections with a first layer adjacent the substrate comprising a first metal and a second layer over the first layer comprising a second metal, and second sections having a composition comprising an alloy of the first metal and the second metal.

13. A method for patterning an electrically conductive layer on a substrate, the method comprising:
applying localized heating along the surface of the electrically conductive layer, wherein the electrically conductive layer comprises a first layer adjacent the substrate comprising a first metal and a second layer on the first layer comprising a second metal and wherein the localized heating forms an alloy of the first metal and the second metal in a pattern to form a patterned surface according to the locations at which the heat is applied.

14. The method of claim 13 further comprising selectively etching the patterned surface to selectively remove the alloy as well as the first metal layer at locations below the alloy while substantially leaving the remaining second metal as well as the first metal at locations below the second metal to form a patterned electrically conductive structure.

15. The method of claim 14 wherein the etching step is performed using a chemical etchant that selectively removed the alloy wherein the second metal is resistant to the chemical etchant.

16. The method of claim 14 further comprising performing an additional etching step following removal of the alloy and first metal at the locations below the alloy, wherein the additional etching step involves removing the second layer while the first layer remains substantially intact.

17. The method of claim 13 wherein the alloy is formed without substantially ablating the metal.

18. The method of claim 13 further comprising selectively etching the patterned surface to selectively remove the second metal as well as the first metal layer at locations below the second metal while substantially leaving the alloy and as well as the first metal layer at locations below the alloy to form a patterned electrically conductive structure.

19. The method of claim 13 wherein the localized heating is applied by scanning an intense light source across a surface of the electrically conductive layer.

20. The method of claim 19 wherein the light source has a wavelength in the visible or infrared portions of the electromagnetic spectrum.

21. The method of claim 19 wherein the intense light source is a pulsed infrared laser.

22. The method of claim 21 wherein a turn in the pattern is formed through connected linear movements with angles between them of at least about 95 degrees.

23. The method of claim 19 wherein the pattern has the spacing between at least some adjacent segments of the un-alloyed layers is no more than about 250 microns.

24. The method of claim 13 wherein the substrate comprises an inorganic semiconductor.

25. The method of claim 13 wherein the substrate comprises silicon.

26. The method of claim 24 further comprising:
selectively etching the alloy to form a patterned electrically conductive structure wherein the patterned conductive structure comprises two disconnected conductive patterns; and
incorporating the patterned conductive structure into a photovoltaic device wherein the patterned conductive structure is connected to electrical contacts of the patterned structure with the disconnected conductive patterns being connected to different electrical polarities.
